(19) United States
(12) Patent Application Publication
(10) Pub. No.: US 2026/0150583 A1
(43) Pub. Date: May 28, 2026

(54) MAGNETIC DEVICE

(71) Applicant: SP-AITH Limited, Sheung Wan Hong Kong (CN)

(72) Inventor: Hiroaki Yoda, Tsukuba-shi Ibaraki (JP)

(73) Assignee: SP-AITH Limited, Sheung Wan Hong Kong (CN)

(21) Appl. No.: 19/453,316

(22) Filed: Jan. 20, 2026

Related U.S. Application Data
(63) Continuation of application No. PCT/JP2023/029712, filed on Aug. 17, 2023.

(51) Int. Cl. H10N 50/10; G11C 11/16; H10N 50/85

(52) U.S. Cl. CPC H10N 50/10; G11C 11/161; G11C 11/1675; H10N 50/85

(57) ABSTRACT

According to one embodiment, a magnetic device includes a first conductive member and a first element section. The first element section includes a first magnetic layer, a second magnetic layer, and a first nonmagnetic layer. The first magnetic layer is provided between the first conductive member and the second magnetic layer. The first nonmagnetic layer is provided between the first magnetic layer and the second magnetic layer in a first direction from the first magnetic layer to the second magnetic layer. The first magnetic layer includes a first magnetic region provided between the first conductive member and the first nonmagnetic layer, a second magnetic region provided between the first conductive member and the first magnetic region, and a first intermediate region provided between the second magnetic region and the first magnetic region. The first intermediate region includes Ir.

### CROSS-REFERENCE TO RELATED APPLICATIONS

This is a continuation application of International Application PCT/JP2023/029712, filed on August 17, 2023; the entire contents of which are incorporated herein by reference.

### FIELD

Embodiments described herein relate generally to a magnetic device.

### BACKGROUND

Magnetic devices including magnetic layers are applied to a variety of applications. It is desired to improve the characteristics of magnetic devices.

### BRIEF DESCRIPTION OF THE DRAWINGS

FIG. 1 is a schematic cross-sectional view illustrating a magnetic device according to a first embodiment;

FIG. 2 is a schematic cross-sectional view illustrating a magnetic device of a reference example;

FIG. 3 is a schematic cross-sectional view illustrating a magnetic device of a reference example;

FIG. 4 is a graph illustrating the characteristics of magnetic devices;

FIG. 5 is a schematic cross-sectional view illustrating a magnetic device according to the first embodiment;

FIG. 6 is a schematic cross-sectional view illustrating a magnetic device according to the first embodiment;

FIG. 7 is a schematic cross-sectional view illustrating a magnetic device according to the first embodiment;

FIG. 8 is a graph illustrating the characteristics of a magnetic device;

FIG. 9 is a schematic perspective view illustrating a magnetic device according to a second embodiment;

FIG. 10 is a schematic plan view illustrating the magnetic device according to the second embodiment;

FIG. 11 is a schematic cross-sectional view illustrating the magnetic device according to the second embodiment;

FIG. 12 is a schematic cross-sectional view illustrating a magnetic device according to the second embodiment;

FIG. 13 is a micrograph image illustrating the magnetic device according to the second embodiment;

FIG. 14 is a schematic cross-sectional view illustrating a magnetic device according to the second embodiment;

FIG. 15 is a schematic cross-sectional view illustrating a magnetic device according to the second embodiment;

FIG. 16 is a schematic cross-sectional view illustrating a magnetic device according to the second embodiment;

FIG. 17 is a schematic cross-sectional view illustrating a magnetic device according to a third embodiment;

FIG. 18 is a schematic cross-sectional view illustrating a magnetic device according to a fourth embodiment; and

FIG. 19 is a schematic cross-sectional view illustrating a magnetic device according to the fourth embodiment.

### DETAILED DESCRIPTION

According to one embodiment, a magnetic device includes a first conductive member and a first element section. The first element section includes a first magnetic layer, a second magnetic layer, and a first nonmagnetic layer. The first magnetic layer is provided between the first conductive member and the second magnetic layer. The first nonmagnetic layer is provided between the first magnetic layer and the second magnetic layer in a first direction from the first magnetic layer to the second magnetic layer. The first magnetic layer includes a first magnetic region provided between the first conductive member and the first nonmagnetic layer, a second magnetic region provided between the first conductive member and the first magnetic region, and a first intermediate region provided between the second magnetic region and the first magnetic region. The first intermediate region includes Ir.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

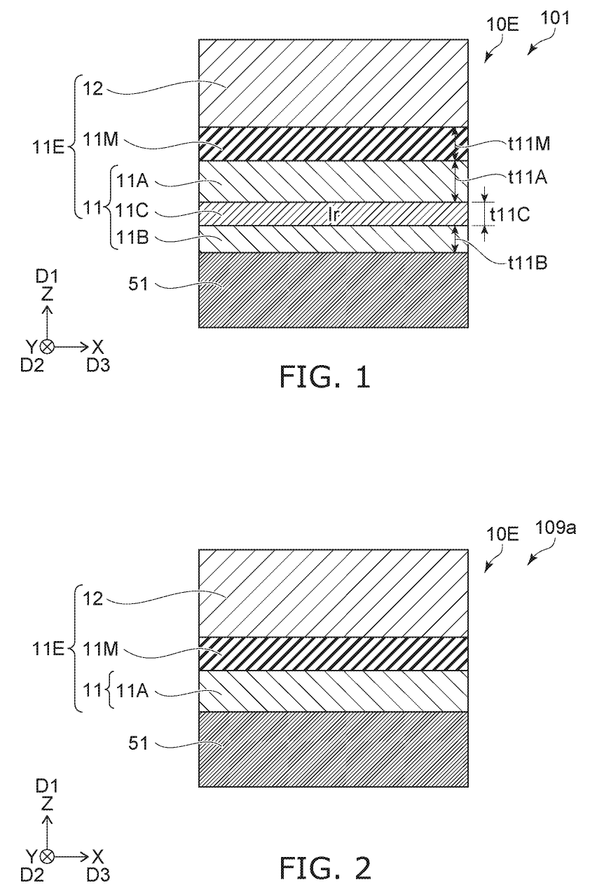

FIG. 1 is a schematic cross-sectional view illustrating a magnetic device according to a first embodiment.

As shown in FIG. 1, a magnetic device 101 according to the embodiment includes a first conductive member 51 and a first element section 11E.

The first element section 11E includes a first magnetic layer 11, a second magnetic layer 12, and a first nonmagnetic layer 11M. The first magnetic layer 11 is provided between the first conductive member 51 and the second magnetic layer 12.

A first direction D1 from the first magnetic layer 11 to the second magnetic layer 12 is defined as a Z-axis direction. One direction perpendicular to the Z-axis direction is defined as an X-axis direction. A direction perpendicular to the Z-axis direction and the X-axis direction is defined as a Y-axis direction. For example, the first magnetic layer 11, the second magnetic layer 12, and the first nonmagnetic layer 11M are along the X-Y plane.

The first nonmagnetic layer 11M is provided between the first magnetic layer 11 and the second magnetic layer 12 in the first direction D1.

The first magnetic layer 11 includes a first magnetic region 11A, a second magnetic region 11B, and a first intermediate region 11C. The first magnetic region 11A is provided between the first conductive member 51 and the first nonmagnetic layer 11M. The second magnetic region 11B is provided between the first conductive member 51 and the first magnetic region 11A. The first intermediate region 11C is provided between the second magnetic region 11B and the first magnetic region 11A. The first intermediate region 11C includes Ir. The first intermediate region 11C is, for example, an Ir layer.

For example, a direction of magnetization of the first magnetic layer 11 is configured to can be controlled by a current flowing through the first conductive member 51. The state of change in magnetization of the first magnetic layer 11 differs depending on the direction of the current. According to a change in the angle between the magnetization of the first magnetic layer 11 and the second magnetic layer 12, the electrical resistance of the first element section 11E changes. For example, the first magnetic layer 11 is a switching layer. The second magnetic layer 12 is, for example, a reference layer.

At this time, the ease of change in magnetization of the first magnetic layer 11 is changed by a voltage between the first conductive member 51 and the second magnetic layer 12. The electrical resistance of the first element section 11E can be controlled by a combination of the voltage and the current. For example, the first conductive member 51 may be provided with a plurality of first element sections 11E. For example, at least one of the plurality of first element sections 11E is selected by the voltage, and the electrical resistance can be controlled.

Thus, the electrical resistance between the first conductive member 51 and the second magnetic layer 12 can be changed by the direction of the current flowing through the first conductive member 51 and the voltage V1 applied between the first conductive member 51 and the second magnetic layer 12. The magnetic device 101 can be used, for example, as an arithmetic element. The magnetic device 101 can be used, for example, as a memory.

The operation of changing electrical resistance corresponds to a write operation. The write operation controls the magnetization of the first magnetic layer 11. After a write operation, the state of magnetization may change due to the influence of thermal fluctuations, for example, and unintended electrical resistance may occur. The time period in which electrical resistance is maintained corresponds to a retention time. The writeable current (threshold current) is preferably small. On the other hand, the retention time is preferably long. Preferably, the retention energy corresponding to the retention time is large.

In the embodiment, the first magnetic layer 11 includes the first intermediate region 11C including Ir. It has been found that by providing such a first intermediate region 11C, the write current can be reduced. It has been found that by providing such a first intermediate region 11C, large retention energy and long retention time can be obtained.

Hereinafter, an examples of magnetic devices 101 will be explained while comparing the characteristics with the reference examples.

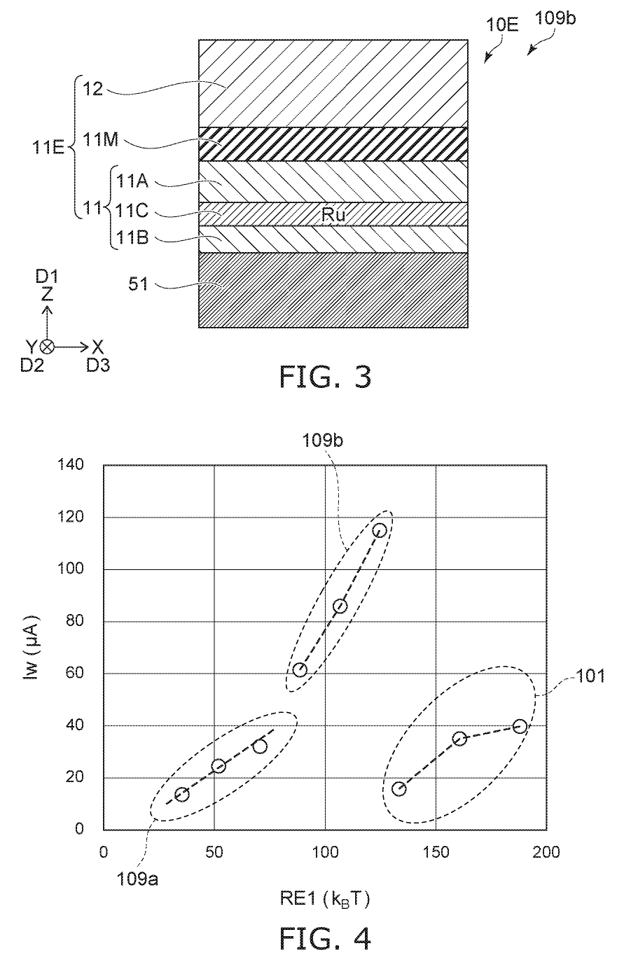

FIGS. 2 and 3 are schematic cross-sectional views illustrating magnetic devices of reference examples.

As shown in FIG. 2, in a magnetic device 109a of the first reference example, the second magnetic region 11B and the first intermediate region 11C are not provided. The configuration of the magnetic device 109a except for this is the same as the configuration of the magnetic device 101.

As shown in FIG. 3, in the magnetic device 109b of the first reference example, the first magnetic layer 11 includes the first magnetic region 11A, the second magnetic region 11B, and the first intermediate region 11C. In the magnetic device 109b, the first intermediate region 11C is a Ru layer. The configuration of the magnetic device 109b except for this is the same as the configuration of the magnetic device 101.

FIG. 4 is a graph illustrating the characteristics of magnetic devices.

FIG. 4 illustrates the calculation results of the characteristics of the magnetic devices 101, 109a, and 109b. In FIG. 4, the horizontal axis is the retention energy RE1. The vertical axis is the write threshold current Iw. It is preferable that the retention energy RE1 is large. It is preferable that the write threshold current Iw is small. In FIG. 4, characteristics are shown when the first element section 11E has three sizes in each of the magnetic devices 101, 109a, and 109b.

As shown in FIG. 4, in the magnetic device 109a of the first reference example, although the write threshold current Iw is small, the retention energy RE1 is small. In the first reference example, the retention time is short and it is difficult to obtain stable characteristics.

As shown in FIG. 4, in the magnetic device 109b of the second reference example, the retention energy RE1 is larger than that of the magnetic device 109a, but the write threshold current Iw is larger. In the second reference example, a large write current is required. For example, current consumption is large. Large currents tend to deteriorate elements.

As shown in FIG. 4, in the magnetic device 101 according to the embodiment, the retention energy RE1 being large is obtained. In the magnetic device 101, the write threshold current Iw is small. In the magnetic device 101, stable characteristics can be obtained. Power consumption can be reduced. Deterioration of the element is suppressed and stable characteristics can be obtained over a long period of time. According to the embodiment, a magnetic device whose characteristics can be improved can be improved.

In the magnetic device 101, the first intermediate region 11C including Ir is provided. For example, the first intermediate region 11C includes an interface facing the first magnetic region 11A and an interface facing the second magnetic region 11B. It is thought that because the first intermediate region 11C includes Ir, perpendicular magnetic anisotropy is generated in the region including these two interfaces. It is thought that the perpendicular magnetic anisotropy makes it easier for the magnetization to change in the first magnetic region 11A and the second magnetic region 11B in switching. This is thought to reduce the write threshold current Iw. On the other hand, after the switching ends and the direction of magnetization changes, the magnetization is relatively stable and it is considered that a large retention energy RE1 can be obtained.

On the other hand, in the second reference example, the first intermediate region 11C including Ru is provided. When Ru is used, it is considered that perpendicular magnetic anisotropy is not generated at the two interfaces of the first intermediate region 11C. Therefore, it is considered that the write threshold current Iw is large in the second reference example.

In the first reference example, perpendicular magnetic anisotropy may be generated at the interface between the first magnetic layer 11 and the first nonmagnetic layer 11M. It is thought that this allows a small write threshold current Iw to be obtained. However, in the first reference example, the magnetization moves as a unit in the first magnetic layer 11. Therefore, the magnetization is relatively unstable and the retention energy RE1 is considered to be small.

In contrast, in the embodiment, the perpendicular magnetic anisotropy is obtained at the two interfaces of the first intermediate region 11C including Ir, and perpendicular magnetic anisotropy is also obtained at the interface between the first magnetic region 11A and the first nonmagnetic layer 11M. Thereby, as a whole, large perpendicular magnetic anisotropy is obtained. As a result, the write threshold current Iw become small. Further, since the first intermediate region 11C including Ir is provided between the first magnetic region 11A and the second magnetic region 11B, these magnetic regions are magnetically coupled, and stable magnetization is obtained after switching. Thereby, it is considered that the retention energy RE1 being large is obtained.

It was found that the write efficiency in the magnetic device 101 according to the embodiment was 3.9 to 4.2 times the write efficiency in the magnetic device 109b of the second reference example. This is considered to be related to the fact that a small write threshold current Iw can be obtained in the magnetic device 101. In the first intermediate region 11C with Ir, higher write efficiency can be obtained than in the first intermediate region 11C with Ru. This is considered to be related to, for example, the difference in elemental properties (e.g., crystal structure, lattice spacing, etc.) between Ir and Ru.

In the embodiment, the first magnetic layer 11 has, for example, an SAF (synthetic anti-ferromagnetic) structure. For example, it is thought that a special effect (high writing efficiency) can be obtained by combining the above-mentioned characteristics of Ir as an element and the SAF structure.

For example, it is preferable that the first magnetic region 11A and the second magnetic region 11B are magnetically coupled. This makes it easy to obtain a stable magnetization. For example, the first magnetic region 11A and the second magnetic region 11B are coupled in antiparallel. For example, the first magnetic region 11A and the second magnetic region 11B may be coupled in parallel.

As shown in FIG. 1, a thickness of the first intermediate region 11C in the first direction D1 is defined as a first intermediate region thickness t11C. It is preferable that the first intermediate region thickness t11C is, for example, not less than 0.3 nm and not more than 0.7 nm. In this case, the first magnetic region 11A and the second magnetic region 11B are coupled in antiparallel. Alternatively, the first intermediate region thickness t11C is preferably, for example, not less than 0.02 nm and less than 0.3 nm. In this case, the first magnetic region 11A and the second magnetic region 11B are coupled in parallel. Alternatively, the first intermediate region thickness t11C is preferably more than 0.7 nm and not more than 5 nm, for example. In this case, the first magnetic region 11A and the second magnetic region 11B are coupled in parallel.

As shown in FIG. 1, a thickness of the first nonmagnetic layer 11M in the first direction D1 is defined as a first nonmagnetic layer thickness t11M. In one example, the first nonmagnetic layer thickness t11M is not less than 0.8 nm and not more than 2 nm.

As shown in FIG. 1, a thickness of the first magnetic region 11A in the first direction D1 is defined a first magnetic region thickness t11A. In one example, the first magnetic region thickness t11A is not less than 0.5 nm and not more than 2 nm.

As shown in FIG. 1, a thickness of the second magnetic region 11B in the first direction D1 is defined as a second magnetic region thickness t11B. In one example, the second magnetic region thickness t11B is not less than 0.7 nm and not more than 3 nm.

The second magnetic region 11B may include, for example, at least one selected from the group consisting of Co and Fe. The second magnetic region 11B includes, for example, Co and Fe. For example, the second magnetic region 11B may include, for example, Co₉₀Fe₁₀.

The first magnetic region 11A may include at least one selected from the group consisting of Co and Fe, for example. As explained below, the first magnetic region 11A may include a plurality of portions having different compositions.

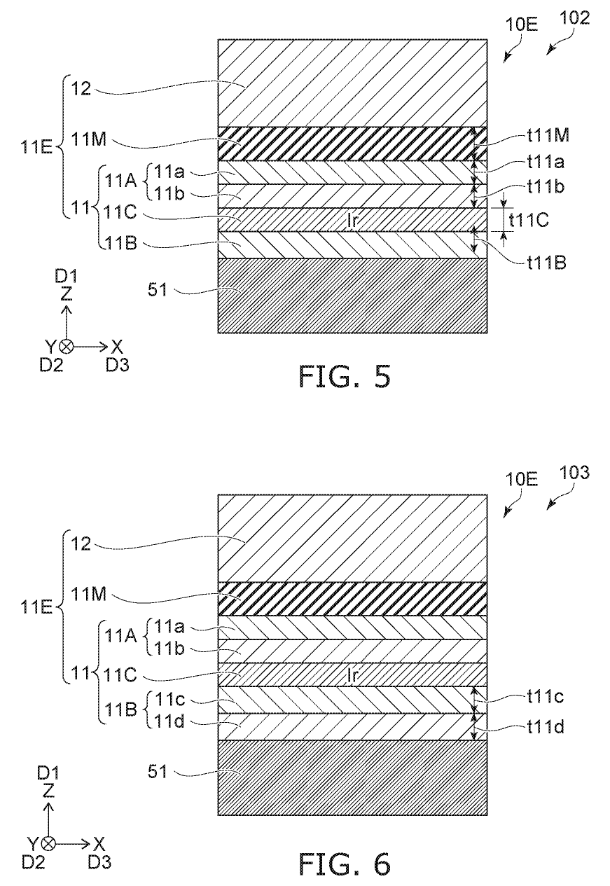

FIG. 5 is a schematic cross-sectional view illustrating a magnetic device according to the first embodiment.

As shown in FIG. 5, in a magnetic device 102 according to the embodiment, the first magnetic region 11A includes a plurality of parts. The configuration of the magnetic device 102 except for this may be the same as the configuration of the magnetic device 101.

In the magnetic device 102, the first magnetic region 11A includes a first magnetic part 11a and a second magnetic part 11b. The second magnetic part 11b is provided between the first intermediate region 11C and the first magnetic part 11a. The first magnetic part 11a includes Co, Fe, and B. The second magnetic part 11b includes Co. For example, the second magnetic part 11b does not include Fe. Alternatively, the Fe concentration in the second magnetic part 11b is lower than the Fe concentration in the first magnetic part 11a. Such a configuration enables more stable magnetization switching.

As shown in FIG. 5, a thickness of the first magnetic part 11a in the first direction D1 is defined as a first magnetic part thickness t11a. In one example, the first magnetic part thickness t11a is not less than 0.3 nm and not more than 4 nm or less.

As shown in FIG. 5, a thickness of the second magnetic part 11b in the first direction D1 is defined as a second magnetic part thickness t11b. In one example, the second magnetic part thickness t11b is not less than 0.3 nm and not more than 3 nm.

FIG. 6 is a schematic cross-sectional view illustrating a magnetic device according to the first embodiment.

As shown in FIG. 6, in a magnetic device 103 according to the embodiment, the second magnetic region 11B includes a plurality of parts. The configuration of the magnetic device 103 except for this may be the same as the configuration of the magnetic device 101 or the magnetic device 102.

In the magnetic device 103, the second magnetic region 11B includes a third magnetic part 11c and a fourth magnetic part 11d. The fourth magnetic part 11d is provided between the first conductive member 51 and the third magnetic part 11c. The concentration of Fe in the fourth magnetic part 11d is higher than the concentration of Fe in the third magnetic part 11c. For example, the third magnetic part 11c and the fourth magnetic part 11d include Co and Fe. The concentration of Fe changes in the third magnetic part 11c and the fourth magnetic part 11d.

The low concentration of Fe in the third magnetic part 11c makes it easier to obtain, for example, a face-centered cubic crystal lattice. This makes it easy to obtain good lattice matching between the third magnetic part 11c and the first intermediate region 11C including Ir. The high concentration of Fe in the fourth magnetic part 11d makes it easier to obtain a small write threshold current Iw, for example.

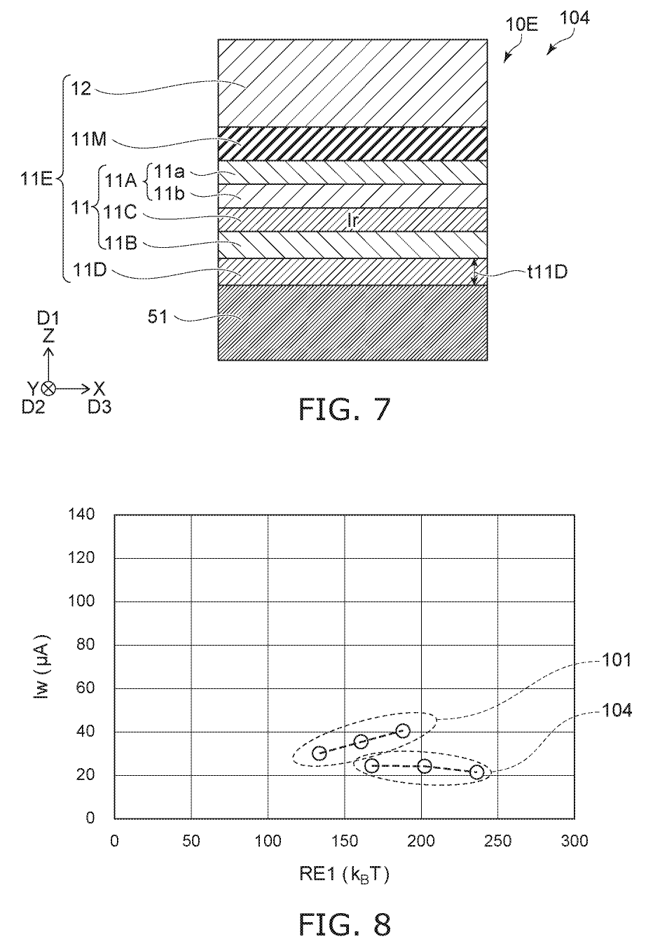

FIG. 7 is a schematic cross-sectional view illustrating a magnetic device according to the first embodiment.

As shown in FIG. 7, in a magnetic device 104 according to the embodiment, the first element section 11E includes a first intermediate layer 11D. The configuration of the magnetic device 104 except for this may be the same as the configuration of the magnetic device 101, the magnetic device 102, or the magnetic device 103.

In the first element section 11E of the magnetic device 104, the first intermediate layer 11D is provided between the first conductive member 51 and the first magnetic layer 11. The first intermediate layer 11D is nonmagnetic.

For example, the first intermediate layer 11D includes at least one material selected from the group consisting of a first material, a second material, and a third material. The first material includes oxygen and at least one selected from the group consisting of Ta, Hf, Gd, Pt, Mg, Ir, Ti, and Cu. The second material includes nitrogen and at least one selected from the group consisting of Ta, Hf, Gd, Pt, Mg, Ir, and Ti. The third material includes at least one selected from the group consisting of Ta, Hf, Gd, Pt, Mg, Ir, and Ti. The first intermediate layer 11D including such a material enables more stable control of magnetization.

FIG. 8 is a graph illustrating the characteristics of a magnetic device.

FIG. 8 illustrates the calculation results of the characteristics of the magnetic device 104. In FIG. 7, the horizontal axis is the retention energy RE1. The vertical axis is the write threshold current Iw. FIG. 8 also illustrates the characteristics of the magnetic device 101. In FIG. 8, the characteristics of the magnetic devices 101 and 104 when the first element section 11E has three sizes are shown.

As shown in FIG. 8, a larger retention energy RE1 can be obtained in the magnetic device 104 provided with the first intermediate layer 11D compared to the magnetic device 101. In the magnetic device 104, a smaller write threshold current Iw can be obtained compared to the magnetic device 101.

In the magnetic device 104, the first intermediate layer 11D is considered to function as a switching assist layer. The first intermediate layer 11D is considered to effectively transmit the spin effect from the first conductive member 51 to the first magnetic layer 11 without any adverse effects, for example. For example, it is thought that the first intermediate layer 11D stabilizes the magnetization of the first magnetic layer 11.

In the magnetic device according to the embodiment, the first conductive member 51 includes, for example, at least one selected from the group consisting of Ta, W, Pt, Hf, Re, Os, Ir, Pd, Cu, Ag, and Au. The first conductive member 51 may include, for example, TaB. With these materials, the magnetization of the first magnetic layer 11 can be efficiently controlled. For example, the effect of Spin Orbit torque can be effectively obtained.

In the embodiment, stress may be applied to the first element section 11E. As will be described later, stress can be applied to the magnetic layer included in the first element section 11E by the structure of the insulating member and the like. This makes it easier to control the magnetization of the magnetic layer. The stress causes distortion in the crystal lattice of the magnetic layer. By combining the structure and the structure including the first intermediate region 11C including Ir, the above-mentioned effects obtained by Ir are more significantly exhibited.

Hereinafter, some examples of configurations that generate stress will be described. In the following description, the above configuration is applied to the first magnetic layer 11. In the following description, the first intermediate layer 11D may be applied.

### Second Embodiment

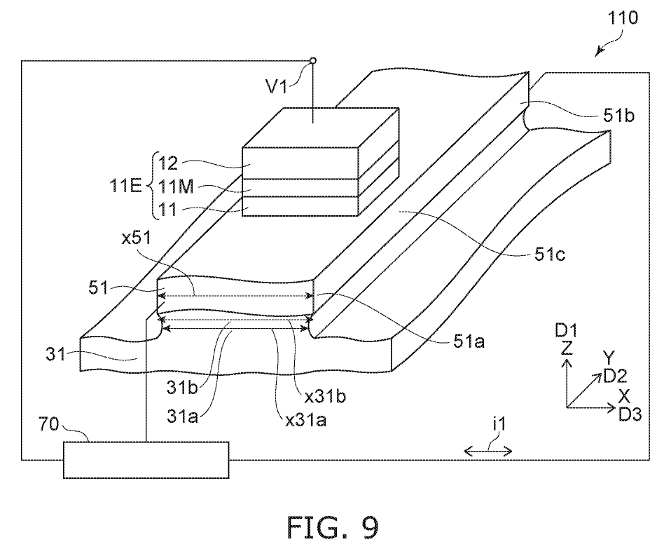

FIG. 9 is a schematic perspective view illustrating a magnetic device according to the second embodiment.

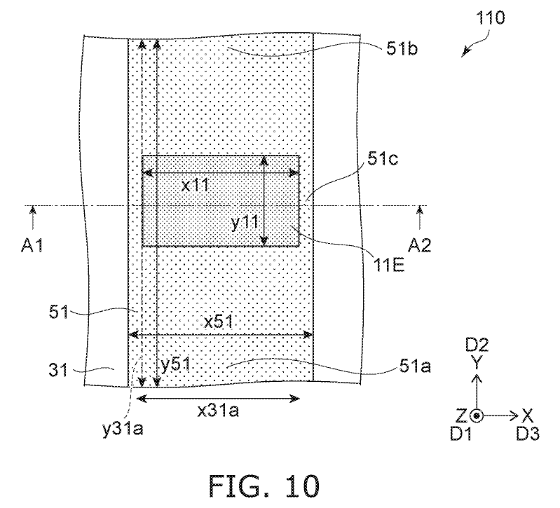

FIG. 10 is a schematic plan view illustrating the magnetic device according to the second embodiment.

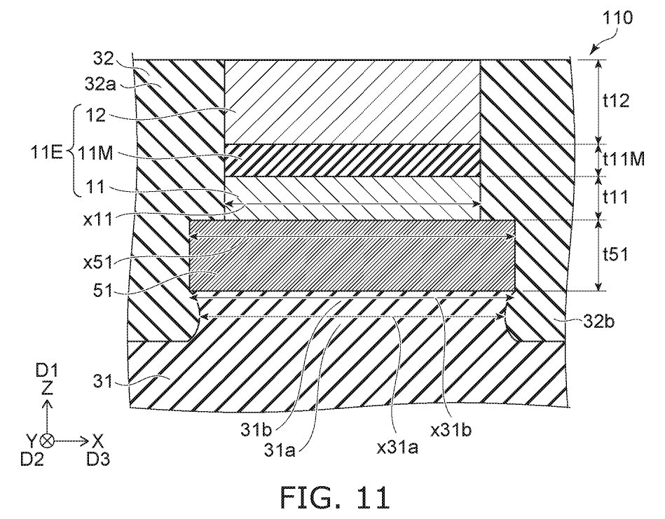

FIG. 11 is a schematic cross-sectional view illustrating the magnetic device according to the second embodiment.

FIG. 11 is a sectional view taken along the line A1-A2 in FIG. 10.

As shown in FIG. 9, a magnetic device 110 according to the embodiment includes the first element section 11E, the first conductive member 51, and a first insulating member 31.

The first element section 11E includes the first magnetic layer 11, the second magnetic layer 12, and the first nonmagnetic layer 11M. The first direction D1 from the first magnetic layer 11 to the second magnetic layer 12 is defined as the Z-axis direction. One direction perpendicular to the Z-axis direction is defined as the Y-axis direction. The direction perpendicular to the Z-axis direction and the Y-axis direction is defined as the X-axis direction.

The first nonmagnetic layer 11M is provided between the first magnetic layer 11 and the second magnetic layer 12 in the first direction D1.

The first conductive member 51 includes a first conductive portion 51a, a second conductive portion 51b, and a third conductive portion 51c. A second direction D2 from the first conductive portion 51a to the second conductive portion 51b crosses the first direction D1. The second direction D2 is, for example, the Y-axis direction. The first conductive member 51 has a stripe shape extending along the second direction D2.

The third conductive portion 51c is provided between the first conductive portion 51a and the second conductive portion 51b in the second direction D2. The first magnetic layer 11 is provided between the third conductive portion 51c and the second magnetic layer 12 in the first direction D1. A region overlapping the first element section 11E in the first direction D1 corresponds to the third conductive portion 51c.

The third conductive portion 51c is provided between a part of the first insulating member 31 and the first element section 11E in the first direction D1. The first insulating member 31 includes a first insulating portion 31a and a second insulating portion 31b. The first insulating portion 31a and the second insulating portion 31b overlap the first conductive member 51 in the first direction D1. The second insulating portion 31b is provided between the first insulating portion 31a and the first conductive member 51 in the first direction D1. For example, the second insulating portion 31b is provided between the first insulating portion 31a and the third conductive portion 51c in the first direction D1.

For example, the first insulating portion 31a is the lower portion. The second insulating portion 31b is provided on the first insulating portion 31a. The first conductive member 51 is provided on the second insulating portion 31b.

As shown in FIGS. 9 and 11, a third direction D3 intersects a plane including the first direction D1 and the second direction D2. The third direction D3 is, for example, the X-axis direction. a length of the first insulating portion 31a along the third direction D3 is defined as a first insulating portion width x31a. A length of the second insulating portion 31b along the third direction D3 is defined as a second insulating portion width x31b. In the embodiment, the first insulating portion width x31a is narrower than the second insulating portion width x31b. Such a configuration provides stable characteristics. Stable operation can be obtained.

As shown in FIG. 9, a controller 70 may be provided. The controller 70 may be included in the magnetic device 110. The controller 70 may be provided separately from the magnetic device 110. The controller 70 is configured to supply a current i1 to the first conductive member 51. The current i1 has a direction from the first conductive portion 51a to the second conductive portion 51b or a direction from the second conductive portion 51b to the first conductive portion 51a. The direction of the current i1 can be controlled by the controller 70, for example.

For example, the direction of magnetization of the first magnetic layer 11 can be controlled by the current i1. The state of change in magnetization of the first magnetic layer 11 differs depending on the direction of the current i1. According to a change in the angle between the magnetization of the first magnetic layer 11 and the second magnetic layer 12, the electrical resistance of the first element section 11E changes. For example, the first magnetic layer 11 is a switching layer. The second magnetic layer 12 is, for example, a reference layer.

On the other hand, the controller 70 can apply a voltage V1 between the first conductive member 51 and the second magnetic layer 12. The ease of change of the magnetization of the first magnetic layer 11 is changed by the voltage V1. The electrical resistance of the first element section 11E can be controlled by the combination of the voltage V1 and the current i1. For example, a plurality of first element sections 11E may be provided in one first conductive member 51. For example, at least one of the plurality of first element sections 11E is selected by the voltage V1, and the electrical resistance can be controlled.

Thus, the electrical resistance between the first conductive member 51 and the second magnetic layer 12 can be changed by the direction of the current i1 flowing through the first conductive member 51 and the voltage V1 applied between the first conductive member 51 and the second magnetic layer 12.

The magnetic device 110 can be used, for example, as an arithmetic element. The magnetic device 110 can be used as a memory, for example.

As already explained, in the embodiment, the first insulating portion width x31a is narrower than the second insulating portion width x31b. It is thought that by providing such a first insulating member 31, anisotropic stress is effectively applied to the first element section 11E. Thereby, the magnetization (for example, the magnetization of the first magnetic layer 11) included in the first element section 11E is controlled. For example, good retention characteristics can be obtained. This provides stable characteristics. Stable operation can be obtained.

Generally, when trying to obtain good retention characteristics, the write current tends to increase. Alternatively, if an attempt is made to reduce the write current, the retention characteristics tend to deteriorate. In contrast, in the embodiment, anisotropic stress is generated depending on the shape of the first insulating member 31. By utilizing the anisotropic stress from the first insulating member 31, it is possible to reduce the write current while obtaining good retention characteristics.

As shown in FIG. 10, a length of the first insulating portion 31a along the second direction D2 is defined as a first insulating portion length y31a. The first insulating portion length y31a is longer than the first insulating portion width x31a (see FIG. 11). The first insulating portion length y31a is, for example, the length of a stripe. Anisotropic stress is generated because the first insulating portion length y31a is longer than the first insulating portion width x31a. For example, the magnetization of the first magnetic layer 11 can be controlled more effectively by the anisotropic stress.

As shown in FIGS. 9 and 11, a length of the first conductive member 51 along the third direction D3 is defined as a first conductive member width x51. The first insulating portion width x31a is narrower than the first conductive member width x51. Anisotropic stress can be effectively obtained.

As shown in FIG. 10, the first conductive member width x51 of the first conductive member 51 along the third direction D3 is shorter than the first conductive member length y51 of the first conductive member 51 along the second direction D2. The first conductive member 51 has a stripe shape extending along the second direction D2.

The first conductive member 51 includes, for example, at least one member selected from the group consisting of Ta, W, Pt, Hf, Re, Os, Ir, Pd, Cu, Ag, and Au. Thereby, the magnetization of the first magnetic layer 11 can be easily controlled by the action based on the current i1 flowing through the first conductive member 51. The action based on the current i1 may include, for example, Spin Orbit torque.

As shown in FIG. 10, a length of the first element section 11E along the third direction D3 is defined as a first element section width x11. In the embodiment, the first element section width x11 is narrower than the first conductive member width x51. Such a configuration makes it easier to control the magnetization of the first magnetic layer 11.

As shown in FIG. 10, a length of the first element section 11E along the second direction D2 is defined as a first element section length y11. For example, the first element section length y11 may be shorter than the first element section width x11. For example, the magnetization of the first magnetic layer 11 can be more easily controlled. It becomes easy to provide a plurality of first element sections 11E with high density along the second direction D2. In the embodiment, the relationship between the first element section length y11 and the first element section width x11 may be arbitrary.

As shown in FIG. 11, the magnetic device 110 may further include a second insulating member 32. In FIGS. 9 and 10, the second insulating member 32 is omitted. As shown in FIG. 11, the second insulating member 32 includes a first insulating region 32a and a second insulating region 32b. The first element section 11E is provided between the first insulating region 32a and the second insulating region 32b in the third direction D3. For example, a second Young's modulus of the second insulating member 32 is lower than a first Young's modulus of the first insulating member 31. The anisotropic stress caused by the first insulating member 31 is more easily applied to the first element section 11E more effectively.

The first insulating member 31 may include, for example, at least one selected from the group consisting of silicon oxide, silicon nitride, silicon oxynitride, and aluminum oxide. Meanwhile, the second insulating member 32 may include a film based on TEOS (tetra ethoxy silane), a SOG (Spin On Glass) film, a resin, or the like.

For example, the first insulating member 31 includes a first element and a second element. The first element includes at least one selected from the group consisting of silicon and aluminum. The second element includes at least one selected from the group consisting of oxygen and nitrogen. On the other hand, the second insulating member 32 includes silicon, oxygen, and carbon. Alternatively, the second insulating member 32 may include resin.

In the embodiment, a first conductive member thickness t51 (see FIG. 11) of the first conductive member 51 along the first direction D1 is preferably, for example, not less than 2 nm and not more than 15 nm. A first magnetic layer thickness t11 (see FIG. 11) of the first magnetic layer 11 along the first direction D1 is preferably, for example, not less than 0.7 nm and not more than 5 nm. A first nonmagnetic layer thickness t11M (see FIG. 11) of the first nonmagnetic layer 11M along the first direction D1 is preferably, for example, not less than 0.8 nm and not more than 2 nm. A second magnetic layer thickness t12 (see FIG. 11) of the second magnetic layer 12 along the first direction D1 is preferably, for example, not less than 1 nm and not more than 6 nm.

In the embodiment, the first nonmagnetic layer 11M includes, for example, at least one selected from the group consisting of MgO, CaO, SrO, TiO, VO, NbO, and Al₂O₃. The first element section 11E is, for example, a TMR (Tunnel Magneto Resistance) element.

In the embodiment, the first magnetic layer 11 preferably includes, for example, CoₓFe₁₋ₓB. The composition ratio x is preferably not less than 0.1 and not more than 0.6. For example, good device characteristics can be easily obtained. For example, it is easy to obtain a large resistance change. For example, it is easy to obtain highly stable magnetization. It is easy to obtain small write current. For example, it becomes easier to obtain these characteristics at the same time. The concentration of B (boron) in CoₓFe₁₋ₓB is preferably, for example, not less than 5 atm% and not more than 30 atm%.

As explained below, the second magnetic layer 12 may include a plurality of stacked films.

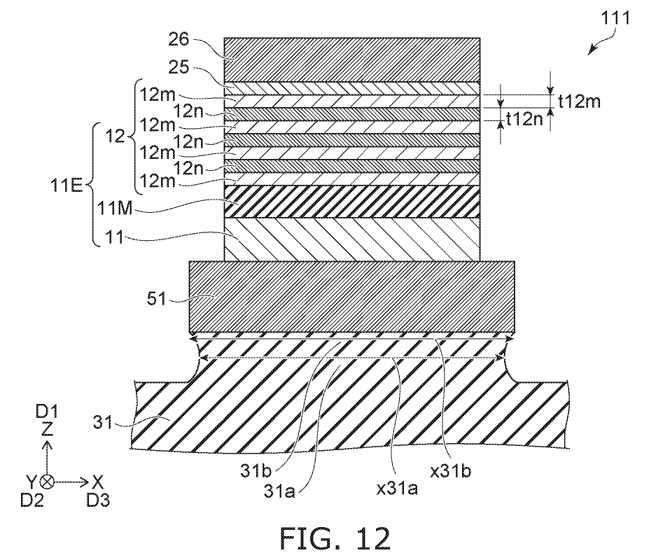

FIG. 12 is a schematic cross-sectional view illustrating a magnetic device according to the second embodiment.

As shown in FIG. 12, in a magnetic device 111 according to the embodiment, the second magnetic layer 12 includes a plurality of magnetic films 12m and a plurality of nonmagnetic films 12n. The configuration of the magnetic device 111 except for this may be the same as the configuration of the magnetic device 110.

In the first direction D1, one of the plurality of magnetic films 12m is provided between one of the plurality of nonmagnetic films 12n and another one of the plurality of nonmagnetic films 12n. In the first direction D1, one of the plurality of nonmagnetic films 12n is provided between one of the plurality of magnetic films 12m and another one of the plurality of magnetic films 12m. The second magnetic layer 12 has, for example, an SAF (synthetic anti-ferromagnetic) structure. In the second magnetic layer 12, more stable magnetic properties can be easily obtained.

The plurality of nonmagnetic films 12n include, for example, at least one selected from the group consisting of Ru and Ir. It is preferable that a nonmagnetic film thickness t12n of one of the plurality of nonmagnetic films 12n along the first direction D1 is, for example, not less than 0.2 nm and not more than 2.0 nm.

The plurality of magnetic films 12m include, for example, at least one selected from the group consisting of Fe and Co. It is preferable that the magnetic film thickness t12m of one of the plurality of magnetic films 12m along the first direction D1 is, for example, not less than 0.2 nm and not more than 5.0 nm.

As shown in FIG. 12, the magnetic device 111 may include a conductive layer 26. The second magnetic layer 12 is provided between the first nonmagnetic layer 11M and the conductive layer 26. The conductive layer 26 includes, for example, at least one selected from the group consisting of Cu, Al, and Au. The conductive layer 26 is, for example, an electrode.

As shown in FIG. 12, the magnetic device 111 may include an intermediate conductive layer 25. The intermediate conductive layer 25 is provided between second magnetic layer 12 and conductive layer 26. The intermediate conductive layer 25 includes, for example, at least one selected from the group consisting of Ti and Ta. The intermediate conductive layer 25 is, for example, a cap layer. The second magnetic layer 12 being stable can be easily obtained.

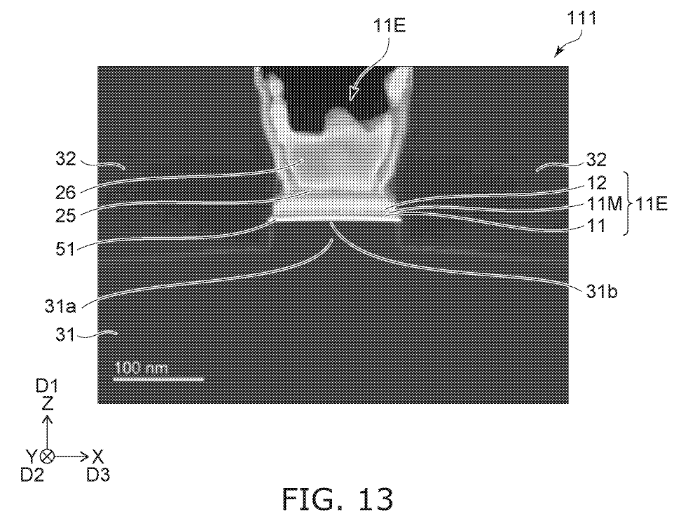

FIG. 13 is a micrograph image illustrating the magnetic device according to the second embodiment.

FIG. 13 is a HAADF-STEM (High-Angle Annular Dark Field Scanning transmission electron microscopy) image of the magnetic device 111. As shown in FIG. 13, in the magnetic device 111, the first insulating member 31 includes the first insulating portion 31a and the second insulating portion 31b. The width (x31a: see FIG. 11) of the first insulating portion 31a along the X-axis direction is narrower than the width (x31b: see FIG. 11) of the second insulating portion 31b along the X-axis direction. The width of the first insulating portion 31a along the X-axis direction is narrower than the width (x51: see FIG. 11) of the first conductive member 51 along the X-axis direction. Such a configuration can be obtained by over-etching the first insulating member 31 in processing of the first insulating member 31.

As shown in FIG. 13, the width (x11: see FIG. 11) of the first element section 11E along the X-axis direction may be narrower than the width of the first conductive member 51 along the X-axis direction.

As shown in FIG. 13, in the X-Z cross section, the first conductive member 51 may be curved in a convex shape from the first insulating portion 31a toward the first element section 11E. The first conductive member 51 may be deformed depending on the stress.

For example, in a first sample corresponding to the magnetic device 111, the retention characteristic is 150 kBT or more. This value corresponds to being non-volatile for more than 10 years. The write current threshold in the first sample is less than 50 μA. On the other hand, in a second sample of the reference example, the width (x31a) of the first insulating portion 31a along the X-axis direction is the same as the width (x51) of the first conductive member 51 along the X-axis direction. In the second sample, the retention characteristics are approximately 50 kBT to 80 kBT. The write current threshold in the second sample is greater than 50 μA, for example between 50 μA and 75 μA. Thus, in the magnetic device (magnetic device 111, etc.) according to the embodiment, good retention characteristics and a small write current can be obtained.

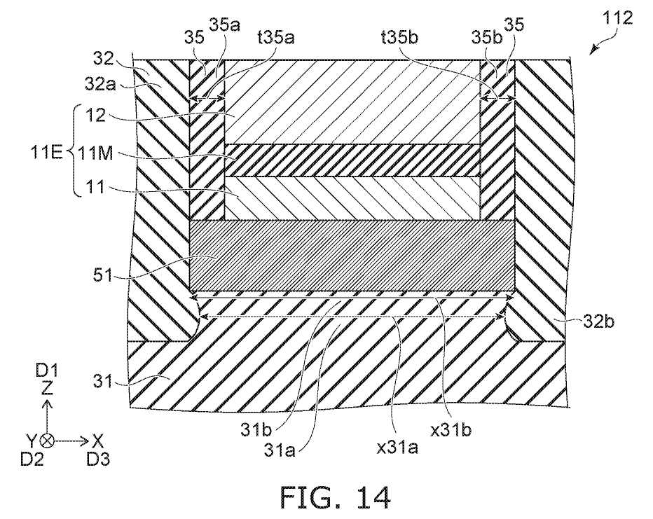

FIG. 14 is a schematic cross-sectional view illustrating a magnetic device according to the second embodiment.

As shown in FIG. 14, the magnetic device 112 according to the embodiment further includes an intermediate insulating member 35. The configuration of the magnetic device 112 except for this may be the same as the configuration of the magnetic device 110 or the magnetic device 111.

The intermediate insulating member 35 includes a first intermediate insulating portion 35a and a second intermediate insulating portion 35b. The first intermediate insulating portion 35a is provided between the first insulating region 32a and the first element section 11E in the third direction D3. The second intermediate insulating portion 35b is provided between the first element section 11E and the second insulating region 32b in the third direction D3. A Young's modulus of the intermediate insulating member 35 is higher than the second Young's modulus.

The intermediate insulating member 35 may include, for example, at least one selected from the group consisting of silicon oxide, silicon nitride, silicon oxynitride, and aluminum oxide. The intermediate insulating member 35 includes, for example, at least one member selected from the group consisting of silicon and aluminum, and at least one member selected from the group consisting of oxygen and nitrogen. On the other hand, the second insulating member 32 includes silicon, oxygen, and carbon. Alternatively, the second insulating member 32 may include resin.

The intermediate insulating member 35 functions as a passivation film, for example. The first element section 11E being stable can be easily obtained. A first intermediate insulating portion thickness t35a of the first intermediate insulating portion 35a along the third direction D3 is preferably, for example, not less than 1 nm and not more than 5 nm. A second intermediate insulating portion thickness t35b of the second intermediate insulating portion 35b along the third direction D3 is preferably, for example, not less than 1 nm and not more than 5 nm. Good protective properties are obtained. Stress based on the first insulating member 31 is applied to the first element section 11E without being damaged.

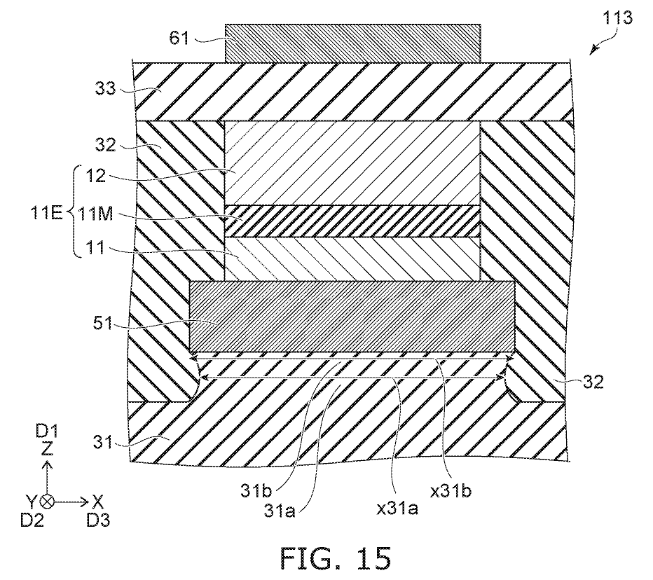

FIG. 15 is a schematic cross-sectional view illustrating a magnetic device according to the second embodiment.

As shown in FIG. 15, the magnetic device 113 according to the embodiment further includes a third insulating member 33. The configuration of the magnetic device 113 except for this may be the same as the configuration of the magnetic device 110, the magnetic device 111, or the magnetic device 112.

In the magnetic device 113, the first element section 11E is provided between the third conductive portion 51c and at least a part of the third insulating member 33 in the first direction D1. A third Young's modulus of the third insulating member 33 is lower than the first Young's modulus of the first insulating member 31. The third insulating member 33 may include a TEOS-based film, an SOG film, a resin, or the like.

In the magnetic device 113, a first conductive layer 61 may be provided. The first conductive layer 61 is, for example, a wiring. The third insulating member 33 having a low Young's modulus is provided between the first element section 11E and the first conductive layer 61. By providing the third insulating member 33 with a low Young's modulus, stress caused by the first conductive layer 61 is less likely to be applied to the first element section 11E. A target anisotropic stress is effectively applied to the first magnetic layer 11. Even when the first conductive layer 61 is provided, stable characteristics can be maintained. Stable operation can be obtained.

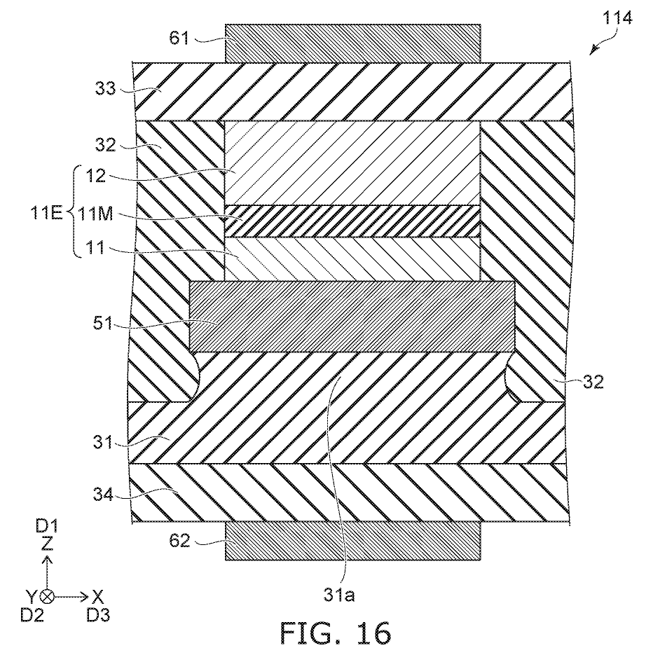

FIG. 16 is a schematic cross-sectional view illustrating a magnetic device according to the second embodiment.

As shown in FIG. 16, the magnetic device 114 according to the embodiment further includes a fourth insulating member 34. The configuration of the magnetic device 114 except for this may be the same as the configuration of the magnetic device 113.

As shown in FIG. 16, the first insulating portion 31a is provided between at least a part of the fourth insulating member 34 and the first conductive member 51 in the first direction D1. A fourth Young's modulus of the fourth insulating member 34 is lower than the first Young's modulus of the first insulating member 31. The fourth insulating member 34 may include a TEOS-based film, an SOG film, a resin, or the like.

In the magnetic device 114, a second conductive layer 62 may be provided. The second conductive layer 62 may be, for example, a wiring. The fourth insulating member 34 is provided between the second conductive layer 62 and the first insulating member 31. By providing the fourth insulating member 34 having a low Young's modulus, stress caused by the second conductive layer 62 is alleviated.

### Third Embodiment

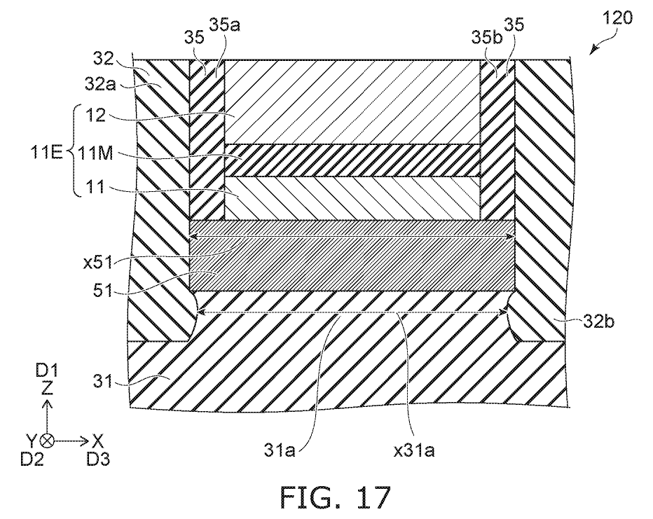

FIG. 17 is a schematic cross-sectional view illustrating a magnetic device according to the third embodiment.

As shown in FIG. 17, a magnetic device 120 according to the embodiment also includes the first element section 11E, the first conductive member 51, and the first insulating member 31. Also in the magnetic device 120, the first element section 11E includes the first magnetic layer 11, the second magnetic layer 12, and the first nonmagnetic layer (see FIG. 9). The first conductive member 51 includes the first conductive portion 51a, the second conductive portion 51b, and the third conductive portion 51c. The first insulating member 31 includes the first insulating portion 31a. The third conductive portion 51c is provided between a part of the first insulating portion 31a and the first element section 11E in the first direction D1. In the magnetic device 120, the configurations of the first element section 11E and the first conductive member 51 may be similar to those in the magnetic device 110 or the magnetic device 111.

The third conductive portion 51c is provided between the first insulating portion 31a and the first magnetic layer 11 in the first direction D1. The first insulating portion width x31a of the first insulating portion 31a along the third direction D3 is narrower than the first conductive member width x51 of the first conductive member 51 along the third direction D3. The third direction D3 crosses a plane including the first direction D1 and the second direction D2. Also in the magnetic device 120, anisotropic stress in the first insulating member 31 and the first conductive member 51 is effectively applied to the first magnetic layer 11. Good retention characteristics can be obtained. Write current can be reduced. Stable characteristics can be obtained. Stable operation can be obtained.

As shown in FIG. 17, also in the magnetic device 120, the first element section width x11 of the first element section 11E along the third direction D3 may be narrower than the first conductive member width x51 (see FIG. 10).

The magnetic device 120 may further include the second insulating member 32. The second insulating member 32 includes the first insulating region 32a and the second insulating region 32b. The first element section 11E is provided between the first insulating region 32a and the second insulating region 32b in the third direction D3. The second Young's modulus of the second insulating member 32 is lower than the first Young's modulus of the first insulating member 31. In the magnetic device 120, the materials of the second insulating member 32 and the first insulating member 31 may be the same as those described in connection with the second embodiment.

As shown in FIG. 17, the magnetic device 120 may further include the intermediate insulating member 35. The intermediate insulating member 35 may include the first intermediate insulating portion 35a and the second intermediate insulating portion 35b. The first intermediate insulating portion 35a is provided between the first insulating region 32a and the first element section 11E in the third direction D3. The second intermediate insulating portion 35b is provided between the first element section 11E and the second insulating region 32b in the third direction D3. The Young's modulus of the intermediate insulating member 35 is higher than the second Young's modulus. The material of the intermediate insulating member 35 may be the same as the material of the intermediate insulating member 35 described in connection with the second embodiment.

The magnetic device 120 may further include the third insulating member 33 (see FIG. 15). The first element section 11E is provided between the third conductive portion 51c and at least a part of the third insulating member 33 in the first direction D1. The third Young's modulus of the third insulating member 33 is lower than the first Young's modulus of the first insulating member 31. The material of the third insulating member 33 may be the same as the material of the third insulating member 33 described regarding the second embodiment.

The magnetic device 120 may further include the fourth insulating member 34 (see FIG. 16). The first insulating portion 31a is provided between at least a part of the fourth insulating member 34 and the first conductive member 51 in the first direction D1. The fourth Young's modulus of the fourth insulating member 34 is lower than the first Young's modulus of the first insulating member 31.

In the magnetic device 120, the first magnetic layer 11 may include CoₓFe₁₋ₓB. The composition ratio x is 0.1 or more and 0.6 or less.

### Fourth Embodiment

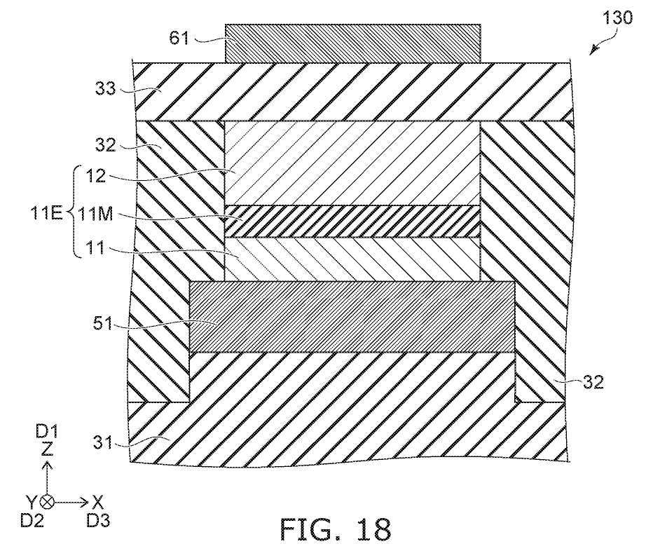

FIG. 18 is a schematic cross-sectional view illustrating a magnetic device according to the fourth embodiment.

As shown in FIG. 18, a magnetic device 130 according to the embodiment includes the first element section 11E, the first conductive member 51, the first insulating member 31, and the third insulating member 33. The configurations of the first element section 11E and the first conductive member 51 in the magnetic device 130 may be the same as those in the magnetic device 110 and the like.

Also in the magnetic device 130, the first conductive member 51 includes the first conductive portion 51a, the second conductive portion 51b, and the third conductive portion 51c. The first insulating member 31 includes the first insulating portion 31a. The third conductive portion 51c is provided between the first insulating portion 31a and the first element section 11E in the first direction D1.

For example, in the magnetic device 130 as well, the length of the first insulating portion 31a along the second direction D2 (first insulating portion length y31a) is different from the length of the first insulating portion 31a along the third direction D3 (first insulating portion length y31a), (see FIG. 11). The first insulating portion 31a is, for example, a stripe. The first insulating portion 31a has a stripe shape extending along the second direction D2. The anisotropic planar shape of the first insulating portion 31a generates anisotropic stress. For example, the magnetization of the first magnetic layer 11 can be controlled more effectively by the anisotropic stress.

In the magnetic device 130, the third conductive portion 51c is provided between a part of the first insulating member 31 and the first element section 11E in the first direction D1. In the magnetic device 130, the first element section 11E is provided between the third conductive portion 51c and at least a part of the third insulating member 33 in the first direction D1. The third Young's modulus of the third insulating member 33 is lower than the first Young's modulus of the first insulating member 31.

By providing the third insulating member 33 with a low Young's modulus, stress caused by other members (for example, the first conductive layer 61, etc.) is alleviated. As a result, anisotropic stress caused by the first insulating member 31 is effectively applied to the first magnetic layer 11. Good retention characteristics can also be obtained in the magnetic device 130. Write current can be reduced. Stable characteristics can be obtained. Stable operation can be obtained.

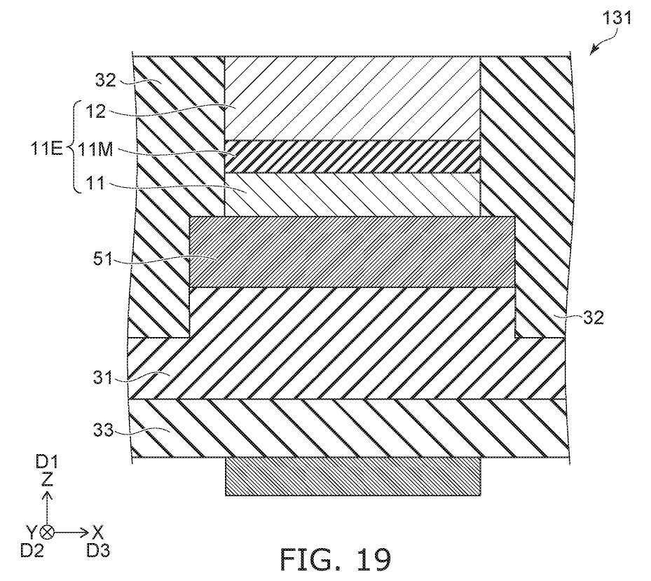

FIG. 19 is a schematic cross-sectional view illustrating a magnetic device according to the fourth embodiment.

As shown in FIG. 19, a magnetic device 131 according to the embodiment includes the first element section 11E, the first conductive member 51, the first insulating member 31, and the third insulating member 33. In the magnetic device 131, the position of the third insulating member 33 is different from the position of the third insulating member 33 in the magnetic device 130. The configuration of the magnetic device 131 except for this may be the same as the configuration of the magnetic device 130.

In the magnetic device 131, the first insulating member 31 is provided between at least a part of the third insulating member 33 and the first conductive member 51 in the first direction D1. The third Young's modulus of the third insulating member 33 is lower than the first Young's modulus of the first insulating member 31. By providing the third insulating member 33 having a low Young's modulus, stress caused by other members (for example, the second conductive layer 62, etc.) is alleviated. As a result, anisotropic stress caused by the first insulating member 31 is effectively applied to the first magnetic layer 11. Good retention characteristics can also be obtained in the magnetic device 131. Write current can be reduced. Stable characteristics can be obtained. Stable operation can be obtained.

In the magnetic device 130 and the magnetic device 131, the first insulating member 31 may include, for example, at least one selected from the group consisting of silicon oxide, silicon nitride, silicon oxynitride, and aluminum oxide. On the other hand, the third insulating member 33 may include a TEOS-based film, an SOG (Spin On Glass) film, a resin, or the like.

For example, the first insulating member 31 includes the first element and the second element. The first element includes at least one selected from the group consisting of silicon and aluminum. The second element includes at least one selected from the group consisting of oxygen and nitrogen. On the other hand, the third insulating member 33 includes silicon, oxygen, and carbon. Alternatively, the third insulating member 33 may include resin.

A second insulating member 32 may be provided in the magnetic device 130 and the magnetic device 131. In the magnetic device 130 and the magnetic device 131, the intermediate insulating member 35 may be provided.

The embodiments may include the following Technical proposals:

### Technical proposal 1

A magnetic device, comprising:

a first conductive member; and

a first element section,

the first element section including a first magnetic layer, a second magnetic layer, and a first nonmagnetic layer,

the first magnetic layer being provided between the first conductive member and the second magnetic layer,

the first nonmagnetic layer being provided between the first magnetic layer and the second magnetic layer in a first direction from the first magnetic layer to the second magnetic layer, and

the first magnetic layer including

a first magnetic region provided between the first conductive member and the first nonmagnetic layer,

a second magnetic region provided between the first conductive member and the first magnetic region, and

a first intermediate region provided between the second magnetic region and the first magnetic region, the first intermediate region including Ir.

### Technical proposal 2

The magnetic device according to Technical proposal 1, wherein

a thickness of the first intermediate region in the first direction is not less than 0.3 nm and not more than 0.7 nm, or

not less than 0.02 nm and less than 0.3 nm, or more than 0.7 nm and not more than 5nm.

### Technical proposal 3

The magnetic device according to Technical proposal 1, wherein

the first magnetic region and the second magnetic region are coupled in antiparallel.

### Technical proposal 4

The magnetic device according to Technical proposal 1, wherein

the first magnetic region and the second magnetic region are coupled in parallel.

### Technical proposal 5

The magnetic device according to Technical proposal 1 or 2, wherein

the first magnetic region includes

a first magnetic part,

a second magnetic part provided between the first intermediate region and the first magnetic part,

the first magnetic part includes Co, Fe and B,

the second magnetic part includes Co, and

the second magnetic part does not include Fe, or a concentration of Fe in the second magnetic part is lower than a concentration of Fe in the first magnetic portion.

### Technical proposal 6

The magnetic device according to any one of Technical proposals 1-5, wherein

the second magnetic layer includes

a third magnetic part, and

a fourth magnetic part provided between the first conductive member and the third magnetic part, and

a concentration of Fe in the fourth magnetic part is higher than a concentration of Fe in the third magnetic part.

### Technical proposal 7

The magnetic device according to any one of Technical proposals 1-6, wherein

the first element section further includes a first intermediate layer provided between the first conductive member and the first magnetic layer, the first intermediate layer being nonmagnetic,

the first intermediate layer includes at least one selected from the group consisting of a first material, a second material, and a third material,

the first material includes oxygen and at least one selected from the group consisting of Ta, Hf, Gd, Pt, Mg, Ir, Ti, and Cu,

the second material includes nitrogen and at least one selected from the group consisting of Ta, Hf, Gd, Pt, Mg, Ir, and Ti, and

the third material includes at least one selected from the group consisting of Ta, Hf, Gd, Pt, Mg, Ir, and Ti.

### Technical proposal 8

The magnetic device according to any one of Technical proposals 1-7, wherein

the first conductive member includes at least one selected from the group consisting of Ta, W, Pt, Hf, Re, Os, Ir, Pd, Cu, Ag, and Au.

### Technical proposal 9

The magnetic device according to any one of Technical proposals 1-8, further comprising:

a first insulating member.

the first conductive member including a first conductive portion, a second conductive portion, and a third conductive portion,

a second direction from the first conductive portion to the second conductive portion crossing the first direction,

the third conductive portion being provided between the first conductive portion and the second conductive portion in the second direction,

the first magnetic layer being provided between the third conductive portion and the second magnetic layer in the first direction,

the third conductive portion being provided between a part of the first insulating member and the first element section in the first direction,

the first insulating member including a first insulating portion and a second insulating portion,

the second insulating portion being provided between the first insulating portion and the first conductive member in the first direction,

a first insulating portion width of the first insulating portion along a third direction being narrower than a second insulating portion width of the second insulating portion along the third direction, and

the third direction crossing a plane including the first direction and the second direction.

### Technical proposal 10

The magnetic device according to Technical proposal 9, wherein

a first insulating portion length of the first insulating portion along the second direction is longer than the first insulating portion width.

### Technical proposal 11

The magnetic device according to Technical proposal 9, wherein

the first insulating portion width is narrower than a first conductive member width along the third direction of the first conductive member.

### Technical proposal 12

The magnetic device according to Technical proposal 11, wherein

a first element section width of the first element section along the third direction is narrower than the first conductive member width.

### Technical proposal 13

The magnetic device according to any one of Technical proposals 9-11, wherein

a first element section width of the first element section along the third direction is longer than a first element section length of the first element section along the second direction.

### Technical proposal 14

The magnetic device according to any one of Technical proposals 9-13, further comprising:

a second insulating member,

the second insulating member including a first insulating region and a second insulating region,

the first element section being provided between the first insulating region and the second insulating region in the third direction,

a second Young's modulus of the second insulating member being lower than a first Young's modulus of the first insulating member.

### Technical proposal 15

The magnetic device according to any one of Technical proposals 9-13, further comprising:

a second insulating member,

the second insulating member including a first insulating region and a second insulating region,

the first element section being provided between the first insulating region and the second insulating region in the third direction,

the first insulating member including a first element and a second element,

the first element including at least one selected from the group consisting of silicon and aluminum, and

the second element including at least one selected from the group consisting of oxygen and nitrogen, and

the second insulating member including silicon, oxygen, and carbon, or the second insulating member including resin.

### Technical proposal 16

The magnetic device according to Technical proposal 14, further comprising:

an intermediate insulating member,

the intermediate insulating member including a first intermediate insulating portion and a second intermediate insulating portion,

the first intermediate insulating portion being provided between the first insulating region and the first element section in the third direction,

the second intermediate insulating portion being provided between the first element section and the second insulating region in the third direction, and

a Young's modulus of the intermediate insulating member being higher than the second Young's modulus.

### Technical proposal 17

The magnetic device according to any one of Technical proposals 9-13, further comprising:

a third insulating member,

the first element section being provided between the third conductive portion and at least a part of the third insulating member in the first direction, and

a third Young's modulus of the third insulating member being lower than a first Young's modulus of the first insulating member.

### Technical proposal 18

The magnetic device according to any one of Technical proposals 9-13, further comprising:

a fourth insulating member,

the first insulating portion being provided between at least a part of the fourth insulating member and the first conductive member in the first direction,

a fourth Young's modulus of the fourth insulating member being lower than a first Young's modulus of the first insulating member.

### Technical proposal 19

The magnetic device according to any one of Technical proposals 1-17, wherein

the first magnetic layer includes CoₓFe₁₋ₓB, and

the x is 0.1 or more and 0.6 or less.

### Technical proposal 20

The magnetic device according to any one of Technical proposals 1-8, further comprising:

a first insulating member,

the first conductive member including a first conductive portion, a second conductive portion, and a third conductive portion,

a second direction from the first conductive portion to the second conductive portion crossing the first direction,

the third conductive portion being provided between the first conductive portion and the second conductive portion in the second direction,

the first magnetic layer being provided between the third conductive portion and the second magnetic layer in the first direction,

the first insulating member including a first insulating portion,

the third conductive portion being provided between a part of the first insulating portion and the first element section in the first direction,

the third conductive portion being provided between the first insulating portion and the first magnetic layer in the first direction,

a first insulating portion width of the first insulating portion along the third direction being narrower than a first conductive member width of the first conductive member along the third direction, and

the third direction crossing a plane including the first direction and the second direction.

### Technical proposal 21

The magnetic device according to Technical proposal 20, wherein

a first element section width of the first element section along the third direction is narrower than the first conductive member width.

### Technical proposal 22

The magnetic device according to Technical proposal 20 or 21, further comprising:

a second insulating member,

the second insulating member including a first insulating region and a second insulating region,

the first element section being provided between the first insulating region and the second insulating region in the third direction, and

a second Young's modulus of the second insulating member being lower than a first Young's modulus of the first insulating member.

### Technical proposal 23

The magnetic device according to Technical proposal 22, further comprising:

an intermediate insulating member,

the intermediate insulating member including a first intermediate insulating portion and a second intermediate insulating portion,

the first intermediate insulating portion being provided between the first insulating region and the first element section in the third direction,

the second intermediate insulating portion being provided between the first element section and the second insulating region in the third direction, and

a Young's modulus of the intermediate insulating member being higher than the second Young's modulus.

### Technical proposal 24

The magnetic device according to Technical proposal 20 or 21, further comprising:

a third insulating member,

the first element section being provided between the third conductive portion and at least a part of the third insulating member in the first direction, and

a third Young's modulus of the third insulating member being lower than a first Young's modulus of the first insulating member.

### Technical proposal 25

The magnetic device according to Technical proposal 20 or 21, further comprising:

a fourth insulating member,

the first insulating portion being provided between at least a part of the fourth insulating member and the first conductive member in the first direction, and

a fourth Young's modulus of the fourth insulating member being lower than a first Young's modulus of the first insulating member.

### Technical proposal 26

The magnetic device according to any one of Technical proposals 20-25, wherein

the first magnetic layer includes CoₓFe₁₋ₓB, and

the x is not less than 0.1 and not more than 0.6.

### Technical proposal 27

The magnetic device according to any one of Technical proposals 1-8, further comprising:

a first insulating member; and

a third insulating member,

the first conductive member including a first conductive portion, a second conductive portion, and a third conductive portion,

a second direction from the first conductive portion to the second conductive portion crossing the first direction,

the third conductive portion being provided between the first conductive portion and the second conductive portion in the second direction,

the first magnetic layer being provided between the third conductive portion and the second magnetic layer in the first direction,

the first insulating member including a first insulating portion,

the third conductive portion being provided between the first insulating portion and the first element section in the first direction,

the first element section being provided between the third conductive portion and at least a part of the third insulating member in the first direction, or the first insulating member being provided between at least a part of the third insulating member and the first conductive member in the first direction, and

a third Young's modulus of the third insulating member being lower than a first Young's modulus of the first insulating member.

According to the embodiment, a magnetic device whose characteristics can be improved can be provided.

According to the embodiment, a magnetic device and an arithmetic device having a simple configuration can be provided.

In the specification of the application, "perpendicular" and "parallel" refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in magnetic devices such as element sections, magnetic layers, nonmagnetic members, magnetic members, intermediate layers, intermediate members, conductive members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all magnetic devices practicable by an appropriate design modification by one skilled in the art based on the magnetic devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

What is claimed is:

1. A magnetic device, comprising:
a first conductive member;
a first element section; and
a first insulating member,
the first element section including a first magnetic layer, a second magnetic layer, and a first nonmagnetic layer,
the first magnetic layer being provided between the first conductive member and the second magnetic layer,
the first nonmagnetic layer being provided between the first magnetic layer and the second magnetic layer in a first direction from the first magnetic layer to the second magnetic layer,
the first magnetic layer including
a first magnetic region provided between the first conductive member and the first nonmagnetic layer,
a second magnetic region provided between the first conductive member and the first magnetic region, and
a first intermediate region provided between the second magnetic region and the first magnetic region, the first intermediate region including Ir,
the first magnetic region and the second magnetic region being coupled in antiparallel,
the first conductive member including a first conductive portion, a second conductive portion, and a third conductive portion,
a second direction from the first conductive portion to the second conductive portion crossing the first direction,
the third conductive portion being provided between the first conductive portion and the second conductive portion in the second direction,
the first magnetic layer being provided between the third conductive portion and the second magnetic layer in the first direction,
the third conductive portion being provided between a part of the first insulating member and the first element section in the first direction,
the first insulating member including a first insulating portion and a second insulating portion,
the second insulating portion being provided between the first insulating portion and the first conductive member in the first direction,
a first insulating portion width of the first insulating portion along a third direction being narrower than a second insulating portion width of the second insulating portion along the third direction,
the third direction crossing a plane including the first direction and the second direction.

2. The magnetic device according to claim 1, wherein
the first magnetic region includes
a first magnetic part, and
a second magnetic part provided between the first intermediate region and the first magnetic part,
the first magnetic part includes Co, Fe and B,
the second magnetic part includes Co, and
the second magnetic part does not include Fe, or a concentration of Fe in the second magnetic part is lower than a concentration of Fe in the first magnetic part.

3. The magnetic device according to claim 1, wherein
the second magnetic layer includes
a third magnetic part, and
a fourth magnetic part provided between the first conductive member and the third magnetic part, and
a concentration of Fe in the fourth magnetic part is higher than a concentration of Fe in the third magnetic part.

4. The magnetic device according to claim 1, wherein
the first element section further includes a first intermediate layer provided between the first conductive member and the first magnetic layer, the first intermediate layer being nonmagnetic,
the first intermediate layer includes at least one selected from the group consisting of a first material, a second material, and a third material,
the first material includes oxygen and at least one selected from the group consisting of Ta, Hf, Gd, Pt, Mg, Ir, Ti, and Cu,
the second material includes nitrogen and at least one selected from the group consisting of Ta, Hf, Gd, Pt, Mg, Ir, and Ti, and
the third material includes at least one selected from the group consisting of Ta, Hf, Gd, Pt, Mg, Ir, and Ti.

5. The magnetic device according to claim 1, wherein
the first conductive member includes at least one selected from the group consisting of Ta, W, Pt, Hf, Re, Os, Ir, Pd, Cu, Ag, and Au.

6. A magnetic device, comprising:
a first conductive member;
a first element section; and
a first insulating member,
the first element section including a first magnetic layer, a second magnetic layer, and a first nonmagnetic layer,
the first magnetic layer being provided between the first conductive member and the second magnetic layer,
the first nonmagnetic layer being provided between the first magnetic layer and the second magnetic layer in a first direction from the first magnetic layer to the second magnetic layer,
the first magnetic layer including
a first magnetic region provided between the first conductive member and the first nonmagnetic layer,
a second magnetic region provided between the first conductive member and the first magnetic region, and
a first intermediate region provided between the second magnetic region and the first magnetic region, the first intermediate region including Ir,
the first magnetic region and the second magnetic region being coupled in antiparallel,
the first conductive member including a first conductive portion, a second conductive portion, and a third conductive portion,
a second direction from the first conductive portion to the second conductive portion crossing the first direction,
the third conductive portion being provided between the first conductive portion and the second conductive portion in the second direction,
the first magnetic layer being provided between the third conductive portion and the second magnetic layer in the first direction,
the third conductive portion being provided between a part of the first insulating member and the first element section in the first direction,
the first insulating member including a first insulating portion and a second insulating portion,
the second insulating portion being provided between the first insulating portion and the first conductive member in the first direction,
a first insulating portion length of the first insulating portion along the second direction being longer than a first insulating portion width of the first insulating portion along a third direction,
the third direction crossing a plane including the first direction and the second direction.

7. The magnetic device according to claim 6, wherein
the first magnetic region includes
a first magnetic part, and
a second magnetic part provided between the first intermediate region and the first magnetic part,
the first magnetic part includes Co, Fe and B,
the second magnetic part includes Co, and
the second magnetic part does not include Fe, or a concentration of Fe in the second magnetic part is lower than a concentration of Fe in the first magnetic part.

8. The magnetic device according to claim 6, wherein
the second magnetic layer includes
a third magnetic part, and
a fourth magnetic part provided between the first conductive member and the third magnetic part, and
a concentration of Fe in the fourth magnetic part is higher than a concentration of Fe in the third magnetic part.

9. The magnetic device according to claim 6, wherein
the first element section further includes a first intermediate layer provided between the first conductive member and the first magnetic layer, the first intermediate layer being nonmagnetic,
the first intermediate layer includes at least one selected from the group consisting of a first material, a second material, and a third material,
the first material includes oxygen and at least one selected from the group consisting of Ta, Hf, Gd, Pt, Mg, Ir, Ti, and Cu,
the second material includes nitrogen and at least one selected from the group consisting of Ta, Hf, Gd, Pt, Mg, Ir, and Ti, and
the third material includes at least one selected from the group consisting of Ta, Hf, Gd, Pt, Mg, Ir, and Ti.

10. The magnetic device according to claim 6, wherein
the first conductive member includes at least one selected from the group consisting of Ta, W, Pt, Hf, Re, Os, Ir, Pd, Cu, Ag, and Au.

11. A magnetic device, comprising:
a first conductive member;
a first element section;
a first insulating member; and
a second insulating member,
the first element section including a first magnetic layer, a second magnetic layer, and a first nonmagnetic layer,
the first magnetic layer being provided between the first conductive member and the second magnetic layer,
the first nonmagnetic layer being provided between the first magnetic layer and the second magnetic layer in a first direction from the first magnetic layer to the second magnetic layer,
the first magnetic layer including
a first magnetic region provided between the first conductive member and the first nonmagnetic layer,
a second magnetic region provided between the first conductive member and the first magnetic region, and
a first intermediate region provided between the second magnetic region and the first magnetic region, the first intermediate region including Ir,
the first magnetic region and the second magnetic region being coupled in antiparallel,
the first conductive member including a first conductive portion, a second conductive portion, and a third conductive portion,
a second direction from the first conductive portion to the second conductive portion crossing the first direction,
the third conductive portion being provided between the first conductive portion and the second conductive portion in the second direction,
the first magnetic layer being provided between the third conductive portion and the second magnetic layer in the first direction,
the third conductive portion being provided between a part of the first insulating member and the first element section in the first direction,
the second insulating member including a first insulating region and a second insulating region,
the first element section being provided between the first insulating region and the second insulating region in a third direction,
a second Young's modulus of the second insulating member being lower than a first Young's modulus of the first insulating member,
the third direction crossing a plane including the first direction and the second direction.

12. The magnetic device according to claim 11, wherein
the first magnetic region includes
a first magnetic part, and
a second magnetic part provided between the first intermediate region and the first magnetic part,
the first magnetic part includes Co, Fe and B,
the second magnetic part includes Co, and
the second magnetic part does not include Fe, or a concentration of Fe in the second magnetic part is lower than a concentration of Fe in the first magnetic part.

13. The magnetic device according to claim 11, wherein
the second magnetic layer includes
a third magnetic part, and
a fourth magnetic part provided between the first conductive member and the third magnetic part, and
a concentration of Fe in the fourth magnetic part is higher than a concentration of Fe in the third magnetic part.

14. The magnetic device according to claim 11, wherein
the first element section further includes a first intermediate layer provided between the first conductive member and the first magnetic layer, the first intermediate layer being nonmagnetic,
the first intermediate layer includes at least one selected from the group consisting of a first material, a second material, and a third material,
the first material includes oxygen and at least one selected from the group consisting of Ta, Hf, Gd, Pt, Mg, Ir, Ti, and Cu,
the second material includes nitrogen and at least one selected from the group consisting of Ta, Hf, Gd, Pt, Mg, Ir, and Ti, and
the third material includes at least one selected from the group consisting of Ta, Hf, Gd, Pt, Mg, Ir, and Ti.

15. The magnetic device according to claim 11, wherein
the first conductive member includes at least one selected from the group consisting of Ta, W, Pt, Hf, Re, Os, Ir, Pd, Cu, Ag, and Au.

16. A magnetic device, comprising:
a first conductive member;
a first element section; and
a first insulating member,
the first element section including a first magnetic layer, a second magnetic layer, and a first nonmagnetic layer,
the first magnetic layer being provided between the first conductive member and the second magnetic layer,
the first nonmagnetic layer being provided between the first magnetic layer and the second magnetic layer in a first direction from the first magnetic layer to the second magnetic layer,
the first magnetic layer including
a first magnetic region provided between the first conductive member and the first nonmagnetic layer,
a second magnetic region provided between the first conductive member and the first magnetic region, and
a first intermediate region provided between the second magnetic region and the first magnetic region, the first intermediate region including Ir,
the first magnetic region and the second magnetic region being coupled in parallel,
the first conductive member including a first conductive portion, a second conductive portion, and a third conductive portion,
a second direction from the first conductive portion to the second conductive portion crossing the first direction,
the third conductive portion being provided between the first conductive portion and the second conductive portion in the second direction,
the first magnetic layer being provided between the third conductive portion and the second magnetic layer in the first direction,
the third conductive portion being provided between a part of the first insulating member and the first element section in the first direction,
the first insulating member including a first insulating portion and a second insulating portion,
the second insulating portion being provided between the first insulating portion and the first conductive member in the first direction,
a first insulating portion width of the first insulating portion along a third direction being narrower than a second insulating portion width of the second insulating portion along the third direction,
the third direction crossing a plane including the first direction and the second direction.

17. The magnetic device according to claim 16, wherein
the first magnetic region includes
a first magnetic part, and
a second magnetic part provided between the first intermediate region and the first magnetic part,
the first magnetic part includes Co, Fe and B,
the second magnetic part includes Co, and
the second magnetic part does not include Fe, or a concentration of Fe in the second magnetic part is lower than a concentration of Fe in the first magnetic part.

18. The magnetic device according to claim 16, wherein
the second magnetic layer includes
a third magnetic part, and
a fourth magnetic part provided between the first conductive member and the third magnetic part, and
a concentration of Fe in the fourth magnetic part is higher than a concentration of Fe in the third magnetic part.

19. The magnetic device according to claim 16, wherein
the first element section further includes a first intermediate layer provided between the first conductive member and the first magnetic layer, the first intermediate layer being nonmagnetic,
the first intermediate layer includes at least one selected from the group consisting of a first material, a second material, and a third material,
the first material includes oxygen and at least one selected from the group consisting of Ta, Hf, Gd, Pt, Mg, Ir, Ti, and Cu,
the second material includes nitrogen and at least one selected from the group consisting of Ta, Hf, Gd, Pt, Mg, Ir, and Ti, and
the third material includes at least one selected from the group consisting of Ta, Hf, Gd, Pt, Mg, Ir, and Ti.

20. The magnetic device according to claim 16, wherein
the first conductive member includes at least one selected from the group consisting of Ta, W, Pt, Hf, Re, Os, Ir, Pd, Cu, Ag, and Au.
